(19) United States
(12) Patent Application Publication
(10) Pub. No.: US 2026/0339394 A1
(43) Pub. Date: Oct. 29, 2026

(54) PORTABLE ELECTRONIC APPARATUS AND METHOD FOR USING THE SAME

(71) Applicant: COMPAL ELECTRONICS, INC., Taipei City (TW)

(72) Inventors: Shuo-Cheng Chueh, Taipei City (TW); Ting-Wei Cheng, Taipei City (TW); Chien Chiu, Taipei City (TW); Kun-Yen Liu, Taipei City (TW); Tzu-Chien Lai, Taipei City (TW)

(73) Assignee: COMPAL ELECTRONICS, INC., Taipei City (TW)

(21) Appl. No.: 19/555,835

(22) Filed: Mar. 3, 2026

Related U.S. Application Data
(60) Provisional application No. 63/792,924, filed on Apr. 23, 2025.
(60) Provisional application No. 63/804,685, filed on May 13, 2025.

(51) Int. Cl. G06F 1/16; A63F 13/24; A63F 13/25; H05K 5/02

(52) U.S. Cl. CPC G06F 1/1652; A63F 13/24; A63F 13/25; H05K 5/0217

(57) ABSTRACT

A portable electronic apparatus and a method for using the same are provided. The portable electronic apparatus includes a first body, a first pivot portion, a second body pivotally connected to the first body through the first pivot portion, and a display. The second body includes a stand portion and two control portions respectively connected to two opposite sides of the stand portion. The display is disposed between the two control portions. A second pivot portion of the display is pivotally connected to the stand portion. When the display is folded onto the first body along with the second body, a display surface of the display faces a same side as the two control portions, thereby placing the portable electronic device in a game mode. When the display is rotated and unfolded relative to the first body along with the second body, the display surface of the display faces away from the two control portions, thereby placing the portable electronic device in a productivity mode.

### CROSS-REFERENCE TO RELATED APPLICATION

This application claims the priority benefits of U.S. provisional application Ser. No. 63/792,924, filed on Apr. 23, 2025 and U.S. provisional application Ser. No. 63/804,685, filed on May 13, 2025. The entirety of each of the above-mentioned patent applications is hereby incorporated by reference herein and made a part of this specification.

### BACKGROUND

### Technical Field

The disclosure relates to an electronic apparatus, and more particularly, to a portable electronic apparatus and a method for using the same.

### Description of Related Art

With the improvement of processor performance, memory capacity, and battery capacity, apparatuses integrating the usage modes of handheld game consoles and laptop computers have been proposed. Most of such apparatuses adopt a sliding cover design, specifically using a controller and a screen fixed to each other as a sliding cover portion, and hiding a physical keyboard beneath the controller and the screen. By sliding the controller and the screen, the physical keyboard may be exposed from the sliding controller and the screen to switch from a game mode to a laptop computer mode. Since the screen may not be rotated relative to the controller, a viewing angle of the screen may not be flexibly switched, resulting in a relatively limited switching of usage modes.

### SUMMARY

The disclosure provides a portable electronic apparatus and a method for using the same, which may perform fast and intuitive switching between different modes.

The disclosure provides a portable electronic apparatus, including a first body, a first pivot portion, a second body, and a display. The second body is pivotally connected to the first body through the first pivot portion, and includes a stand portion and two control portions arranged in parallel. The two control portions are respectively connected to two opposite sides of the stand portion, and the stand portion has a first side facing the first body and a second side opposite to the first side. The display is disposed between the two control portions, and includes a second pivot portion, a first end portion, and a second end portion opposite to the first end portion. The second pivot portion is located between the first end portion and the second end portion. The second pivot portion of the display is pivotally connected to the stand portion of the second body, and the display is adapted to be rotated relative to the stand portion, so that a back side of the display is in contact with the first side or the second side of the stand portion. When the back side of the display is in contact with the second side of the stand portion, and the display is folded onto the first body along with the second body, a display surface of the display faces a same side as the two control portions, so that the portable electronic apparatus is in a game mode. When the display is unfolded relative to the first body along a first rotation direction along with the second body, and the back side of the display is in contact with the first side of the stand portion, the display surface of the display faces away from the two control portions, so that the portable electronic apparatus is in a productivity mode.

The disclosure provides a method for using a portable electronic apparatus, including the above portable electronic apparatus and a computing module disposed in the first body. The method includes the following. In the game mode, the computing module is adapted to process a first signal from the two control portions to control first screen content displayed on the display surface. In the productivity mode, the two control portions are disabled, and the computing module is adapted to process a second signal from the first body to control second screen content displayed on the display surface.

Based on the above, by flipping the second body relative to the first body, the display may be folded onto the first body along with the second body, or further rotated relative to the stand portion after being unfolded relative to the first body along with the second body, so as to adjust the orientation of the display surface of the display relative to the control portion, thereby performing fast and intuitive switching between the game mode and the productivity mode. On the other hand, the computing module may switch the control signal source of the display according to the mode in which the portable electronic apparatus is in, so as to control the content of the display screen according to the input signal from the control portion in the game mode, and control the content of the display screen according to the input signal from the first body in the productivity mode, eliminating the steps of manual setting.

In order for the aforementioned features and advantages of the disclosure to be more comprehensible, embodiments accompanied with drawings are described in detail below.

### BRIEF DESCRIPTION OF THE DRAWINGS

FIG. 1A to FIG. 1D are schematic views illustrating a portable electronic apparatus converting from a game mode to a productivity mode according to an embodiment of the disclosure.

FIG. 1E is a schematic view illustrating the portable electronic apparatus of FIG. 1D converting from the productivity mode to other usage modes.

FIG. 1F is a schematic view illustrating FIG. 1E from another viewing angle.

FIG. 2A to FIG. 2D are schematic views illustrating a portable electronic apparatus converting from the game mode to the productivity mode according to another embodiment of the disclosure.

FIG. 3A is a schematic side view illustrating a portable electronic apparatus according to an embodiment of the disclosure, for illustrating an automatic flipping mechanism of a display.

FIG. 3B is a schematic partial enlarged view of regions B1, B2, and B3 in FIG. 3A.

FIG. 4A is a schematic side view illustrating a portable electronic apparatus according to another embodiment of the disclosure, for illustrating an automatic flipping mechanism of a display.

FIG. 4B is a schematic partial enlarged view of regions B4, B5, and B6 in FIG. 4A.

FIG. 5A to FIG. 5D are schematic side views illustrating portable electronic apparatuses according to different embodiments of the disclosure, for illustrating an unfolding mechanism of a second body.

FIG. 6 is a schematic side view illustrating a portable electronic apparatus according to other embodiments of the disclosure, for illustrating a folding mechanism of the second body.

FIG. 7 is a schematic side view illustrating a portable electronic apparatus according to other embodiments of the disclosure, for illustrating the unfolding mechanism of the second body.

FIG. 8A to FIG. 8C are schematic cross-sectional views of a portable electronic apparatus according to other embodiments of the disclosure.

FIG. 9 is a schematic partial enlarged view of a portable electronic apparatus according to other embodiments of the disclosure.

### DETAILED DESCRIPTION OF DISCLOSED EMBODIMENTS

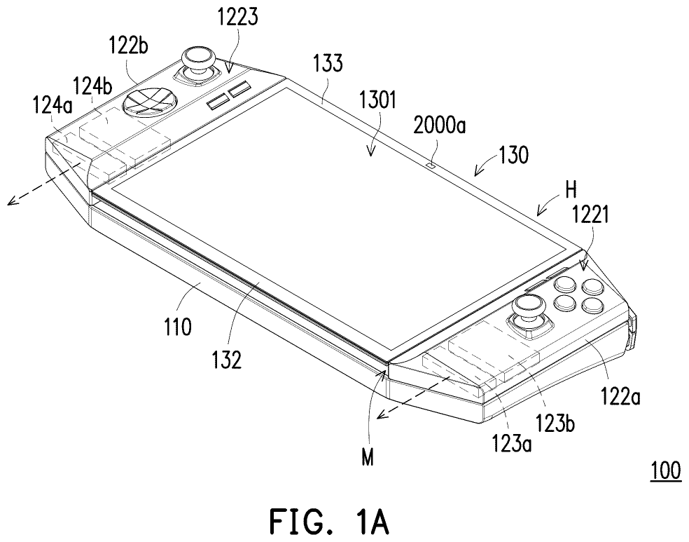

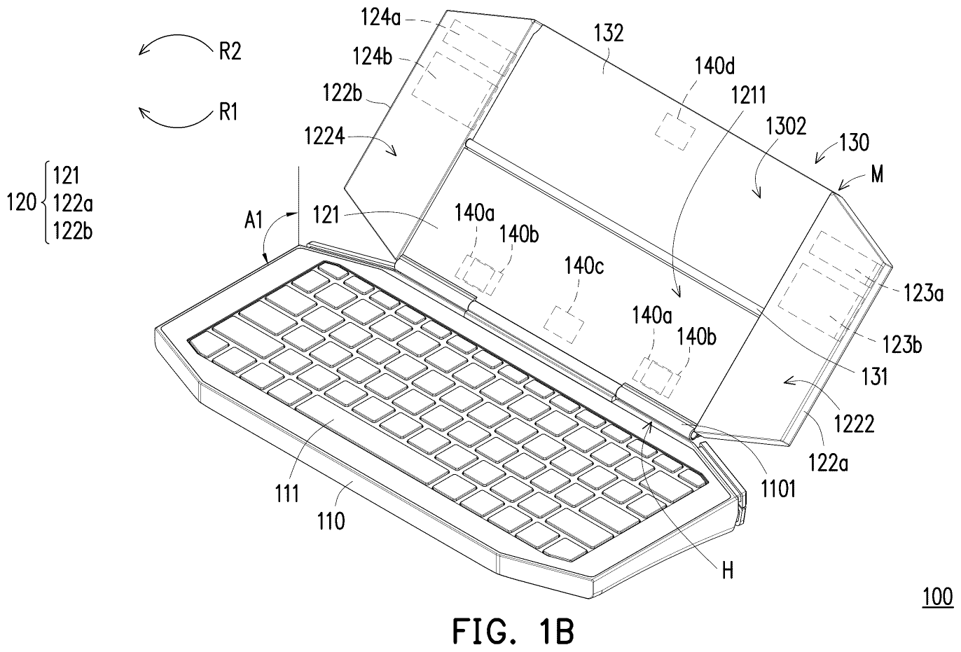

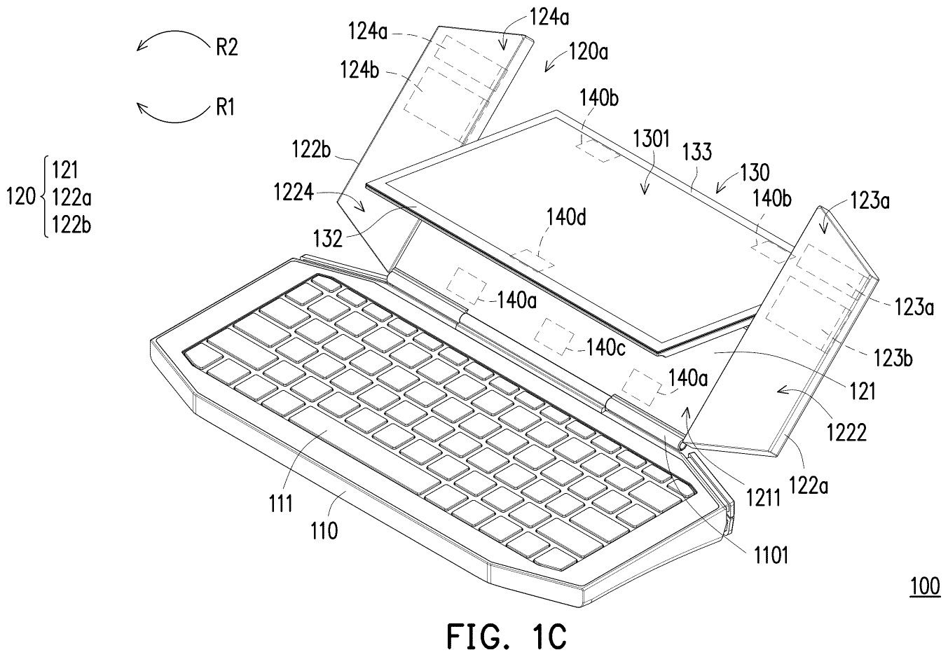

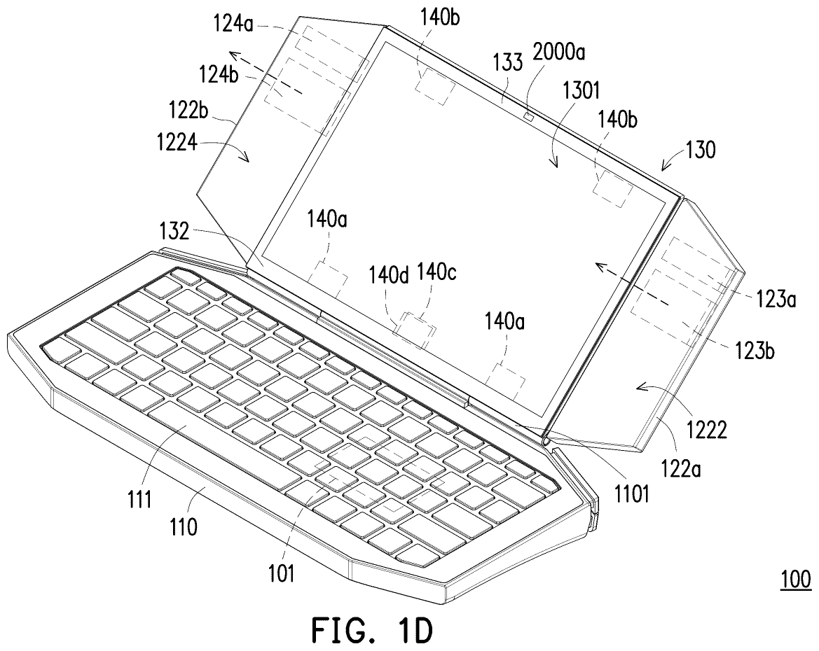

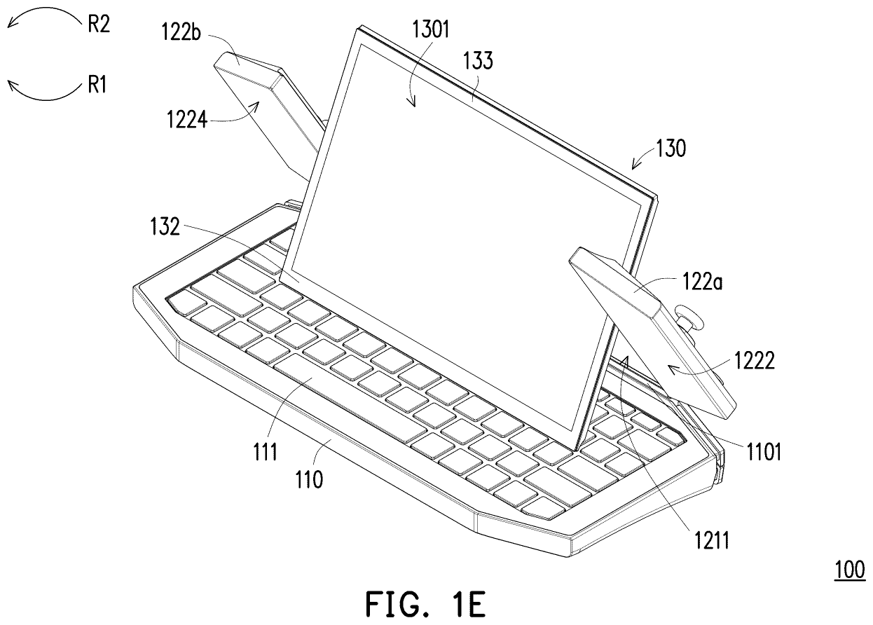

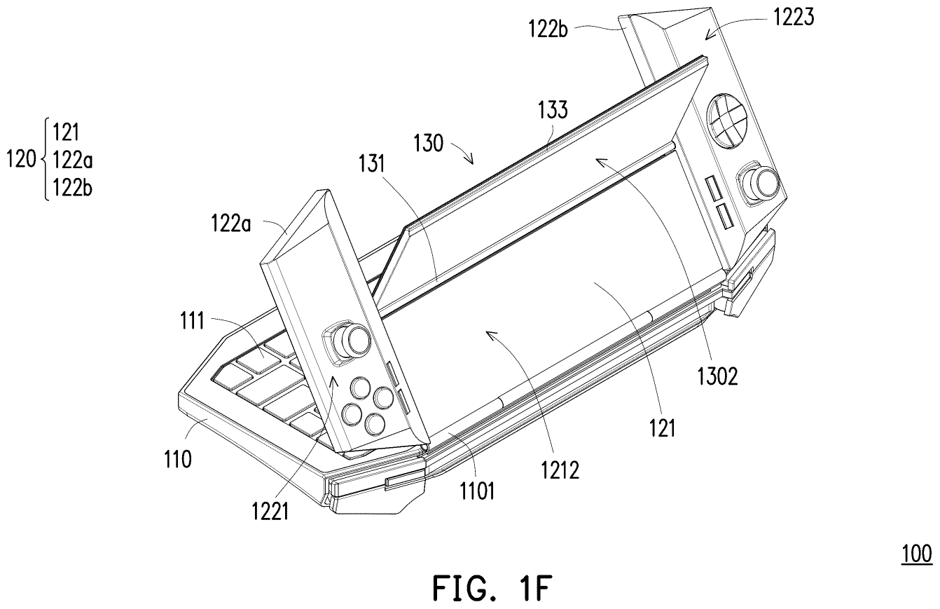

FIG. 1A to FIG. 1D are schematic views illustrating a portable electronic apparatus converting from a game mode to a productivity mode according to an embodiment of the disclosure. Referring to FIG. 1A to FIG. 1D, in this embodiment, a portable electronic apparatus 100 includes a first body 110, a first pivot portion 1101, a second body 120, and a display 130 pivotally connected to the second body 120. In detail, the second body 120 is pivotally connected to the first body 110 through the first pivot portion 1101. The second body 120 has a pivot side H and a movable side M opposite to each other, and the first pivot portion 1101 is located on the pivot side H.

For example, the display 130 may be a liquid crystal display (LCD), a light emitting diode (LED) display or an organic light emitting diode (OLED) display. In an embodiment, the display 130 has glasses-free 3D with stereoscopic imaging technology, providing a richer visual experience.

In the game mode shown in FIG. 1A, the portable electronic apparatus 100 may be used as a handheld game console. The display 130 and the second body 120 are folded onto the first body 110, and a display surface 1301 of the display 130 faces outward to be viewed by a user. On the other hand, a user may choose to manually flip the second body 120 or the display 130 from the movable side M, so that the second body 120 and the display 130 are synchronously unfolded relative to the first body 110 along a first rotation direction R1, so that an input module 111 of the first body 110 is exposed to the outside, as shown in FIG. 1B. That is to say, in the game mode, the input module 111 is covered by the second body 120 and the display 130. For example, the input module 111 includes one or both of a keyboard module and a touchpad module.

As shown in FIG. 1B and FIG. 1C, when the second body 120 and the display 130 are synchronously rotated to be greater than a preset angle A1 (for example, greater than or equal to 45 degrees and less than or equal to 90 degrees), the user may manually operate the display 130, or the display 130 may be automatically rotated relative to the second body 120 along a second rotation direction R2 opposite to the first rotation direction R1 to adjust an orientation of the display surface 1301, so that the display surface 1301 of the display 130 faces a side where the input module 111 is located, thereby converting to the productivity mode shown in FIG. 1D. In the productivity mode, the portable electronic apparatus 100 may be used as a laptop computer, and both the display surface 1301 of the display 130 and the input module 111 face the user for the user to view and operate.

For example, the second body 120 has a gap 120a formed on a side away from a pivot position with the first body 110. The pivot position between the display 130 and the second body 120 is located within the gap 120a, and the display 130 may be flipped through the gap 120a along the first rotation direction R1 or the second rotation direction R2 to avoid interference with the second body 120, thereby achieving free conversion of the portable electronic apparatus 100 between the game mode and the productivity mode.

FIG. 1E is a schematic view illustrating the portable electronic apparatus of FIG. 1D converting from the productivity mode to other usage modes. FIG. 1F is a schematic view illustrating FIG. 1E from another viewing angle. As shown in FIG. 1A and FIG. 1B, the second body 120 includes a stand portion 121, a control portion 122a, and another control portion 122b arranged in parallel with the control portion 122a. The stand portion 121 is pivotally connected to the first body 110, and the control portion 122a and another control portion 122b are respectively connected to two opposite sides of the stand portion 121. As shown in FIG. 1A, FIG. 1B, and FIG. 1F, the stand portion 121 has a first side 1211 facing the first body 110 and a second side 1212 opposite to the first side 1211. In the game mode, the first side 1211 covers a portion of the input module 111, and the second side 1212 is covered by the display 130.

As shown in FIG. 1A and FIG. 1B, the display 130 is disposed between the control portion 122a and another control portion 122b. The display 130 includes a second pivot portion 131, a first end portion 132, and a second end portion 133 opposite to the first end portion 132, and the second pivot portion 131 is located between the first end portion 132 and the second end portion 133. As shown in FIG. 1B and FIG. 1F, the second pivot portion 131 is pivotally connected to the stand portion 121, and the display 130 is adapted to be rotated relative to the stand portion 121 through the second pivot portion 131.

It should be noted that the second pivot portion 131 may adopt different structures according to requirements, for example, a torque pivot that may maintain opening at a specific angle, or a flexible pivot formed by a flexible fabric covering a back side 1302 of the display 130 and the second side 1212 of the stand portion 121 to facilitate a thin and light design.

As shown in FIG. 1A, FIG. 1B, and FIG. 1F, in the game mode, or before the second body 120 and the display 130 are synchronously rotated along the first rotation direction R1 to be greater than the preset angle A1, since the back side 1302 of the display 130 abuts against the second side 1212 of the stand portion 121, a resisting force is generated between the stand portion 121 and the display 130, so that while the second body 120 is rotated along the first rotation direction R1 relative to the first body 110 through the first pivot portion 1101, the display 130 is also pushed to be unfolded relative to the first body 110 along the first rotation direction R1. With this structural configuration, the user from the movable side M, whether flipping the control portion 122a or another control portion 122b, or flipping the display 130, may achieve an effect of the second body 120 and the display 130 being synchronously rotated along the first rotation direction R1.

As shown in FIG. 1B to FIG. 1D and FIG. 1F, when the second body 120 and the display 130 are synchronously rotated along the first rotation direction R1 to be greater than the preset angle A1, the user may then manually operate the display 130, or the display 130 may be automatically rotated relative to the second body 120 along the second rotation direction R2 according to the second pivot portion 131, so that the back side 1302 is separated from the second side 1212 of the stand portion 121, and is moved toward the first side 1211 of the stand portion 121. When the back side 1302 of the display 130 is in contact with the first side 1211 of the stand portion 121, the display 130 stops rotating along the second rotation direction R2, and the portable electronic apparatus 100 converts to the productivity mode.

In other embodiments, the second pivot portion 131 is pivotally connected to the control portion 122a and another control portion 122b, which may also achieve the flipping of the display 130 relative to the stand portion 121.

In the game mode shown in FIG. 1A, the display surface 1301 of the display 130, the control portion 122a, and another control portion 122b face the same side for being viewed or operated by the user. As shown in FIG. 1A and FIG. 1B, the control portion 122a has a first surface 1221 where buttons or joysticks are located and a second surface 1222 opposite to the first surface 1221, and another control portion 122b has a first surface 1223 where the buttons or joysticks are located and a second surface 1224 opposite to the first surface 1223.

In the game mode, the back side 1302 of the display 130, the second surface 1222 of the control portion 122a, and the second surface 1224 of another control portion 122b face the first body 110, and the display surface 1301 of the display 130, the first surface 1221 of the control portion 122a, and the first surface 1223 of another control portion 122b face the same orientation. Specifically, the display surface 1301 of the display 130, the control portion 122a, and another control portion 122b facing the same side refers to the display surface 1301 of the display 130, the first surface 1221 of the control portion 122a, and the first surface 1223 of another control portion 122b facing the same orientation.

In the productivity mode shown in FIG. 1D, the display surface 1301 of the display 130 faces away from the control portion 122a and another control portion 122b to reduce visual interference for the user when viewing the display surface 1301. As shown in FIG. 1D to FIG. 1F, in the productivity mode, the back side 1302 of the display 130, the first surface 1221 of the control portion 122a, and the first surface 1223 of another control portion 122b face the same orientation, and the display surface 1301 of the display 130, the second surface 1222 of the control portion 122a, and the second surface 1224 of another control portion 122b face the same orientation, that is, facing the side where the input module 111 is located. Specifically, the display surface 1301 of the display 130 facing away from the control portion 122a and another control portion 122b refers to the display surface 1301 of the display 130, the first surface 1221 of the control portion 122a, and the first surface 1223 of another control portion 122b facing different orientations.

As shown in FIG. 1D to FIG. 1F, the user may operate the display 130 to rotate relative to the second body 120 along the first rotation direction R1, and drive the second body 120 to rotate relative to the first body 110 along the second rotation direction R2 to adjust a viewing angle of the display surface 1301 of the display 130, so that the portable electronic apparatus 100 converts from the productivity mode shown in FIG. 1D to a theater mode or a reading mode shown in FIG. 1E and FIG. 1F.

As shown in FIG. 1A and FIG. 1D, the control portion 122a is provided with a first speaker 123a and a second speaker 123b. The first speaker 123a is farther from the buttons or joysticks than the second speaker 123b, and a sound output direction of the first speaker 123a is different from a sound output direction of the second speaker 123b. For example, the sound output direction of the first speaker 123a is perpendicular to the sound output direction of the second speaker 123b. In addition, another control portion 122b is provided with a first speaker 124a and a second speaker 124b. The first speaker 124a is farther from the buttons or joysticks than the second speaker 124b, and a sound output direction of the first speaker 124a is different from a sound output direction of the second speaker 124b. For example, the sound output direction of the first speaker 124a is perpendicular to the sound output direction of the second speaker 124b.

In the game mode shown in FIG. 1A, the first speaker 123a and the first speaker 124a are enabled (that is, activated), and the second speaker 123b and the second speaker 124b are disabled (that is, deactivated) to send sound effects to the user by the first speaker 123a and the first speaker 124a. In the productivity mode shown in FIG. 1D, the second speaker 123b and the second speaker 124b are enabled (that is, activated), and the first speaker 123a and the first speaker 124a are disabled (that is, deactivated) to send the sound effects to the user by the second speaker 123b and the second speaker 124b. That is to say, in a process of usage mode conversion, enabled and disabled states of each of the speakers may be automatically switched to provide the best sound effect experience matching the current usage mode.

Referring to FIG. 1A to FIG. 1D, in this embodiment, the portable electronic apparatus 100 further includes a first magnet 140a, a second magnet 140b, a third magnet 140c, and a fourth magnet 140d. In detail, the first magnet 140a is disposed at one end of the stand portion 121 away from the second pivot portion 131, and the second magnet 140b is disposed at the second end portion 133 of the display 130. Before the second body 120 and the display 130 are synchronously rotated along the first rotation direction R1 to be greater than the preset angle A1, the second magnet 140b is aligned with and magnetically attracted to the first magnet 140a to fix the display 130 to the stand portion 121.

In addition, the third magnet 140c is disposed at one end of the stand portion 121 away from the second pivot portion 131, and the fourth magnet 140d is disposed at the first end portion 132 of the display 130. In detail, when the display 130 is rotated relative to the second body 120 along the second rotation direction R2, the first end portion 132 of the display 130 is moved toward the stand portion 121, and the second end portion 133 of the display 130 is moved away from the stand portion 121. The third magnet 140c substantially falls at a path end point of the fourth magnet 140d moved toward the stand portion 121 along with the first end portion 132. When the back side 1302 of the display 130 is in contact with the first side 1211 of the stand portion 121, the fourth magnet 140d is aligned with and magnetically attracted to the third magnet 140c to fix the display 130 to the stand portion 121, so that the portable electronic apparatus 100 is maintained in the productivity mode.

Referring to FIG. 1A and FIG. 1D, in this embodiment, the portable electronic apparatus 100 is provided with a computing module 101 in the first body 110. The computing module 101 may include a central processing unit, or other programmable general purpose or special purpose microprocessors, digital signal processors, image processors, graphics processing units, programmable controllers, application specific integrated circuits, programmable logic devices, other similar processing devices or combinations of these devices.

In the game mode shown in FIG. 1A, the computing module 101 is adapted to process a first signal from the control portion 122a and another control portion 122b to control first screen content displayed on the display surface 1301 of the display 130. For example, the first signal may be a button signal generated when operating buttons of the control portion 122a and another control portion 122b, or a joystick signal generated when operating joysticks of the control portion 122a and another control portion 122b.

In the productivity mode shown in FIG. 1D, the computing module 101 disables (i.e., deactivates and disallows operation of) the control portion 122a and another control portion 122b to prevent unintended operations caused by accidentally touching the buttons or joysticks of the control portion 122a and another control portion 122b. In addition, the computing module 101 is adapted to process a second signal from the first body 110 to control second screen content displayed on the display surface 1301 of the display 130. For example, the second signal may be a signal generated when operating the input module 111.

That is to say, the computing module 101 may switch a control signal source of the display 130 according to the mode in which the portable electronic apparatus 100 is in to control content of a display screen according to an input signal from the control portion 122a and another control portion 122b in the game mode, and to control the content of the display screen according to an input signal from the first body 110 in the productivity mode, eliminating steps of manual setting.

For example, the portable electronic apparatus 100 is provided with a sensor electrically coupled to the computing module 101 in the first body 110, and a corresponding sensing element is disposed in the second body or the display. When the portable electronic apparatus 100 is in the game mode, the sensor senses the sensing element and sends a first detection signal to the computing module 101. The computing module 101 enables (i.e., activates and allows the operations of) the control portion 122a and another control portion 122b based on the first detection signal, and disables (i.e., deactivates and disallows an operation of) the input module 111.

When the portable electronic apparatus 100 is in the productivity mode, the sensor does not sense the sensing element and sends a second detection signal to the computing module 101. The computing module 101 disables (i.e., deactivates and disallows the operations of) the control portion 122a and another control portion 122b based on the second detection signal, and enables (i.e., activates and allows the operation of) the input module 111.

That is to say, the computing module 101may automatically switch enabled and disabled states of the control portion 122a and another control portion 122b and an enabled and disabled states of the input module 111 according to the mode in which the portable electronic apparatus 100 is in, which not only eliminates the steps of manual setting, but also prevents the unintended operations caused by accidental touching.

For example, the sensor and the sensing element may be a combination of a Hall sensor and a magnet, but the disclosure is not limited thereto. On the other hand, a G-sensor, an accelerometer, or a gyroscope may also be disposed in the first body 110, the second body 120, and the display 130, and the mode in which the portable electronic apparatus 100 is in may be determined through such an inertial measurement unit (IMU).

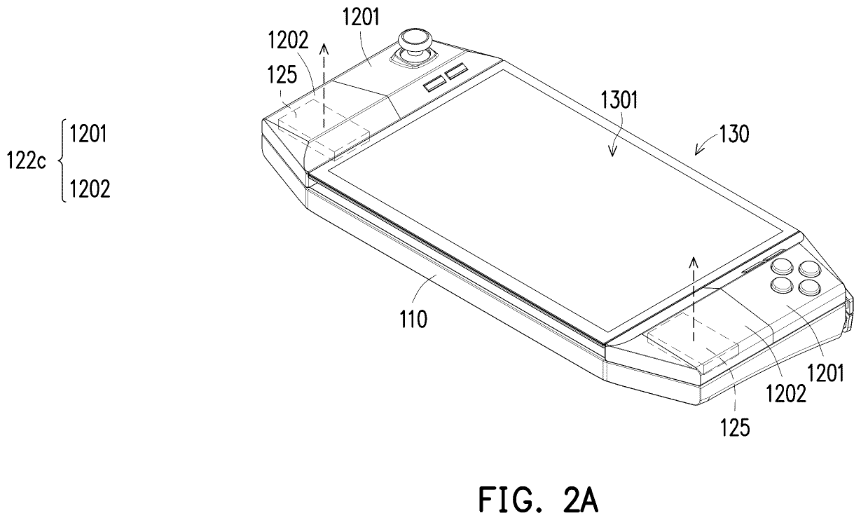

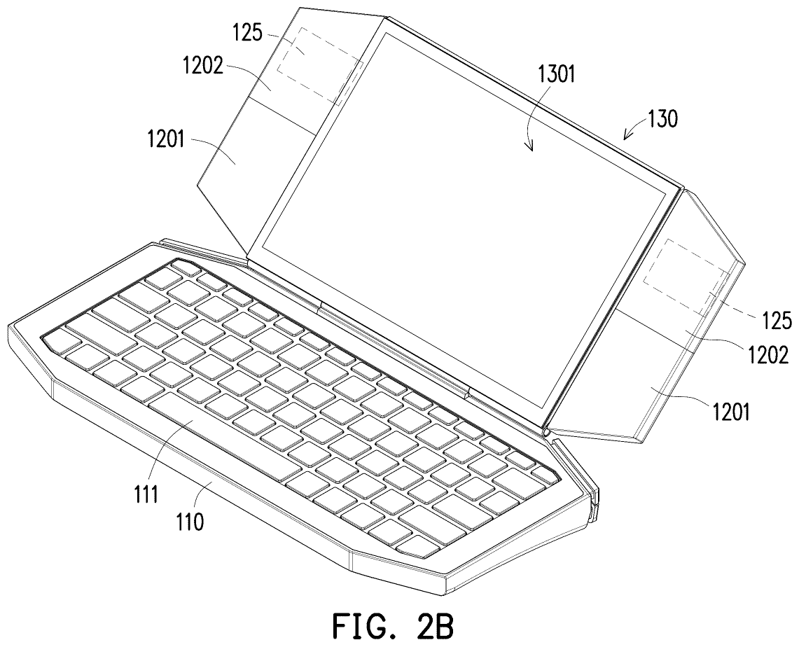

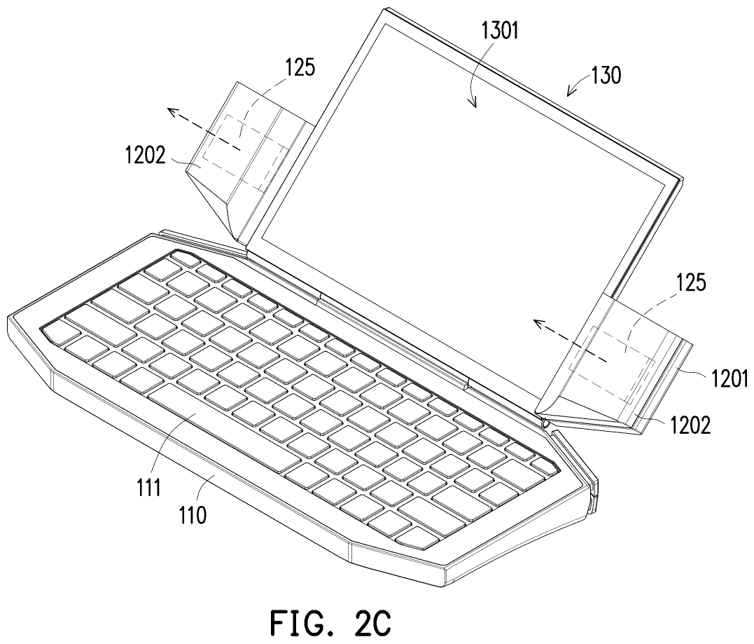

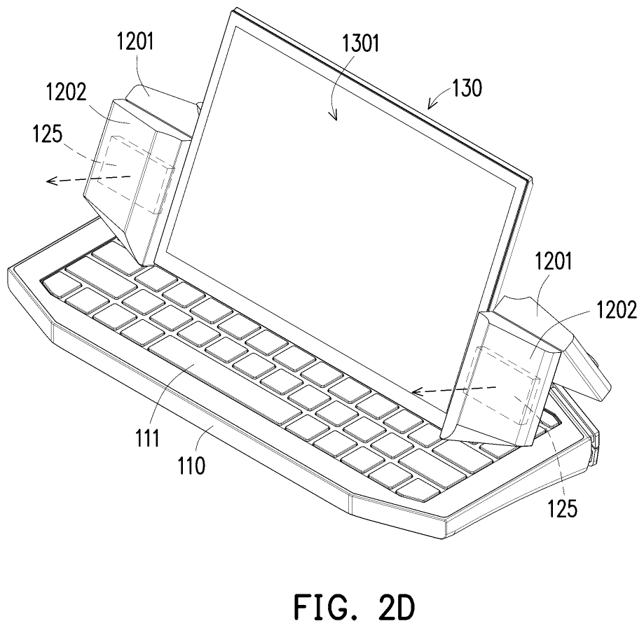

FIG. 2A to FIG. 2D are schematic views illustrating a portable electronic apparatus converting from the game mode to the productivity mode according to another embodiment of the disclosure. Referring to FIG. 2A, the portable electronic apparatus in this embodiment is substantially the same as the portable electronic apparatus 100 in the previous embodiment in structural design, and a main difference lies in configurations of the control portion and the

### Speaker.

In this embodiment, each of control portions 122c is formed by a first module 1201 connected to the stand portion 121 and a second module 1202 pivotally connected to the first module 1201. Each of the first modules 1201 is provided with the buttons or joysticks, and each of the second modules 1202 is provided with a speaker 125. In the game mode shown in FIG. 2A, each of the speakers 125 is enabled (i.e., activated), and a sound output direction is substantially perpendicular to the display surface 1301 of the display 130.

In the productivity mode shown in FIG. 2B and FIG. 2C, the user may rotate the second module 1202, so that the sound output direction of each of the speakers 125 faces the side where the input module 111 is located, so as to send the sound effects to the user. On the other hand, the user may further operate the portable electronic apparatus 100 to convert from the productivity mode shown in FIG. 2C to the theater mode or the reading mode shown in FIG. 2D. During this process, each of the second modules 1202 may be driven to adjust the sound output direction of the speaker 125.

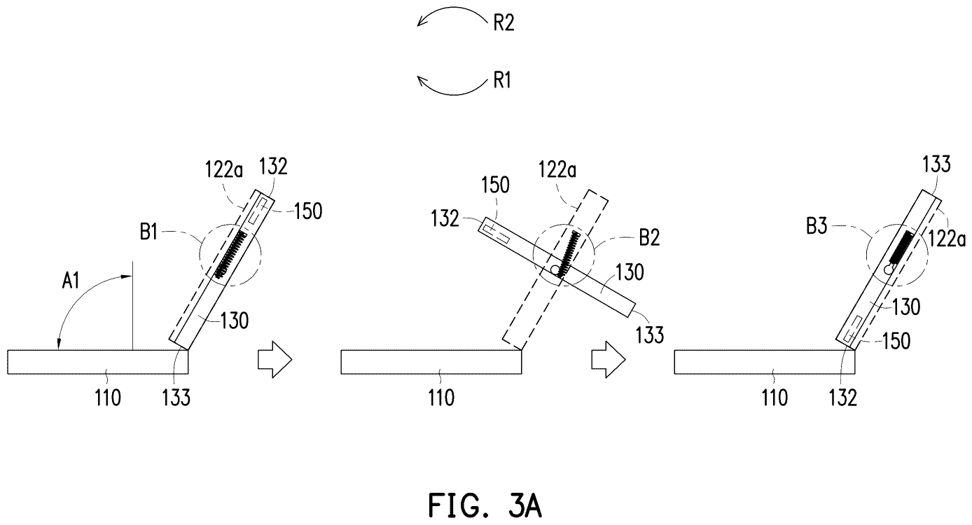

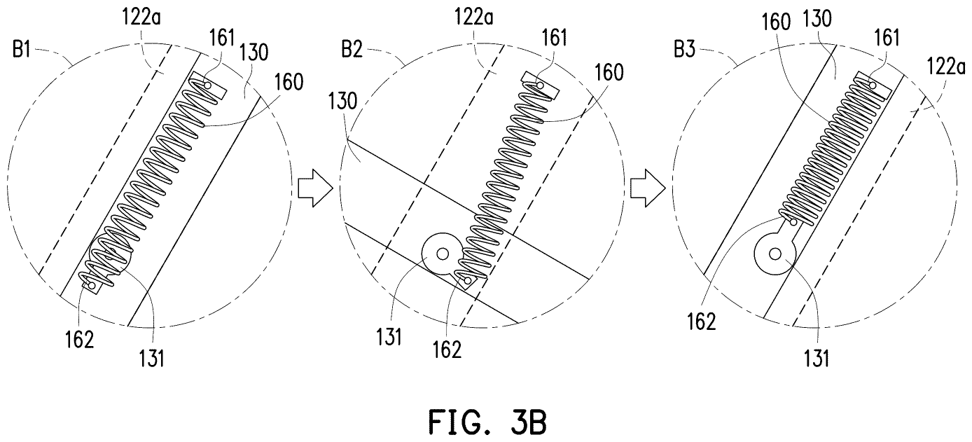

FIG. 3A is a schematic side view illustrating a portable electronic apparatus according to an embodiment of the disclosure, for illustrating an automatic flipping mechanism of the display 130. FIG. 3B is a schematic partial enlarged view of regions B1, B2, and B3 in FIG. 3A. Referring to FIG. 1A to FIG. 1D, the portable electronic apparatus 100 may adopt the automatic flipping mechanism of the display 130 shown in FIG. 3A and FIG. 3B.

As shown in FIG. 3A and FIG. 3B, automatic flipping of the display 130 may be implemented by a driving module including at least a weight block 150 and a spring 160. The weight block 150 is disposed in the display 130, and is located between the first end portion 132 and the second pivot portion 131. In addition, the spring 160 may be a tension spring, and has a fixed end 161 connected to the control portion 122a and a driving end 162 directly connected to the second pivot portion 131.

When the user operates the second body 120 and the display 130 to synchronously rotate relative to the first body 110 along the first rotation direction R1 to be greater than the preset angle A1 from the game mode, the first end portion 132 and the second pivot portion 131 are farther away from the first body 110 than the second end portion 133, a first torque is generated on the second pivot portion 131 through the weight block 150, and the spring 160 generates a second torque opposite to the first torque on the second pivot portion 131. Since the second torque is greater than the first torque, the spring 160 may drive the display 130 to rotate relative to the second body 120 along the second rotation direction R2, so as to automatically convert the portable electronic apparatus 100 to the productivity mode.

Referring to FIG. 1A to FIG. 1D and FIG. 1F together, during a process of converting from the game mode to the productivity mode, the back side 1302 of the display 130 switches from being in contact with the second side 1212 of the stand portion 121 to being in contact with the first side 1211. In addition, the display 130 is in contact with the second side 1212 with the second end portion 133 before being rotated along the first rotation direction R1 to be greater than the preset angle A1, and is in contact with the first side 1211 with the first end portion 132 in the productivity mode.

As shown in FIG. 3A and FIG. 3B, in the productivity mode, the second end portion 133 and the second pivot portion 131 are farther away from the first body 110 than the first end portion 132, and the weight block 150 and the fixed end 161 of the spring 160 are respectively located on two opposite sides of the second pivot portion 131. In addition, before the display 130 is rotated along the first rotation direction R1 to be greater than the preset angle A1, the weight block 150 and the fixed end 161 of the spring 160 are located on the same side of the second pivot portion 131.

As shown in FIG. 3B, a force application position of the driving end 162 of the spring 160 on the second pivot portion 131 is located outside an axle, so that elastic force applied by the spring 160 to the second pivot portion 131 forms a torque due to having a distance from the axle. As shown in FIG. 3A and FIG. 3B, when the display 130 is rotated along the second rotation direction R2 to be less than the preset angle A1, the weight block 150 generates a third torque on the second pivot portion 131, and the third torque is in the same direction as the second torque. The second torque and the third torque together form a greater resultant moment to drive the second pivot portion 1311 to rotate along the second rotation direction R2, thereby accelerating the flipping of the display 130.

It should be particularly noted that if the rotation directions caused by the two torques on the second pivot portion 131 are the same, it means that the two torques are torques in the same direction. Conversely, if the rotation directions caused by the two torques on the second pivot portion 131 are opposite, it means that the two torques are torques in an opposite direction.

In other embodiments, the spring 160 may adopt a torsion spring, which may also implement the automatic flipping of the display 130.

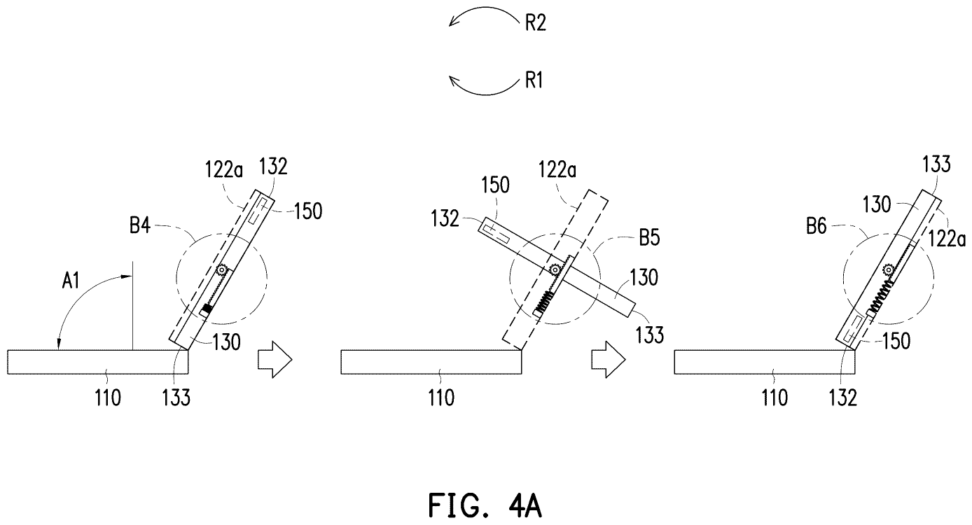

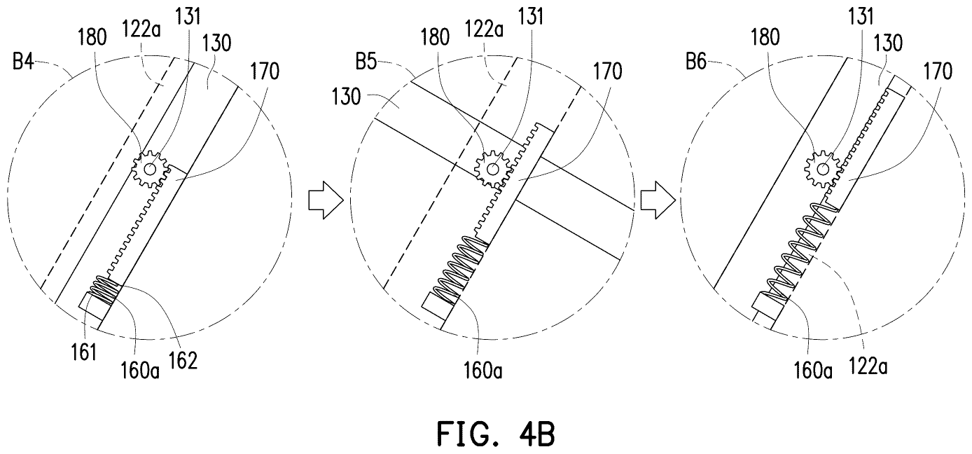

FIG. 4A is a schematic side view illustrating a portable electronic apparatus according to another embodiment of the disclosure, for illustrating the automatic flipping mechanism of the display 130. FIG. 4B is a schematic partial enlarged view of regions B4, B5, and B6 in FIG. 4A. Referring to FIG. 1A to FIG. 1D, the portable electronic apparatus 100 may adopt the automatic flipping mechanism of the display 130 shown in FIG. 4A and FIG. 4B. The automatic flipping mechanism of the display 130 shown in FIG. 4A and FIG. 4B is substantially the same in design principle as the automatic flipping mechanism of the display 130 shown in FIG. 3A and FIG. 3B, and differences are described below.

As shown in FIG. 4A and FIG. 4B, the automatic flipping of the display 130 may be implemented by a driving module including at least a weight block 150a, a spring 160a, and a rack 170. Further, the spring 160a may be a compression spring, and has the fixed end 161 connected to the control portion 122a and the driving end 162 indirectly connected to the second pivot portion 131. Furthermore, the second pivot portion 131 is sleeved with a gear 180. The driving end 162 of the spring 160a is abutted against the rack 170, and the rack 170 is meshed with the gear 180.

Elastic force of the spring 160a may drive the rack 170 to slide, so that the rack 170 drives the gear 180, so as to synchronously drive the second pivot portion 131 to rotate along the second rotation direction R2. That is, the spring 160a generates a torque on the second pivot portion 131 through meshing of the rack 170 and the gear 180.

As shown in FIG. 4A and FIG. 4B, before the display 130 is rotated along the first rotation direction R1 to be greater than the preset angle A1, the weight block 150a and the spring 160a are respectively located on the two opposite sides of the second pivot portion 131. In the productivity mode, the weight block 150a and the spring 160a are located on the same side of the second pivot portion 131.

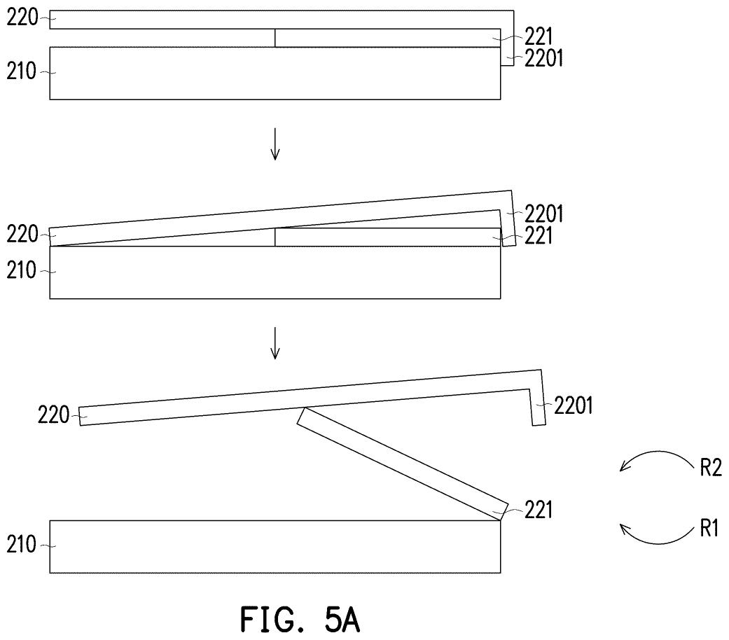

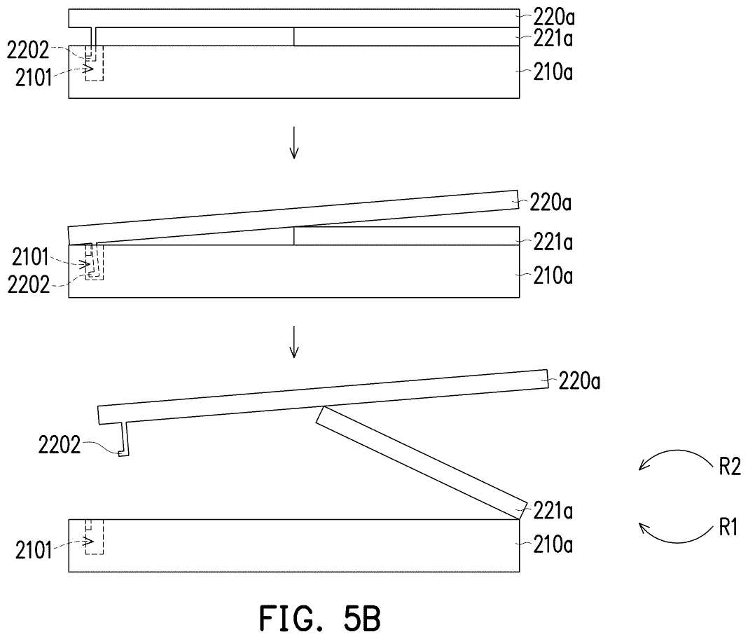

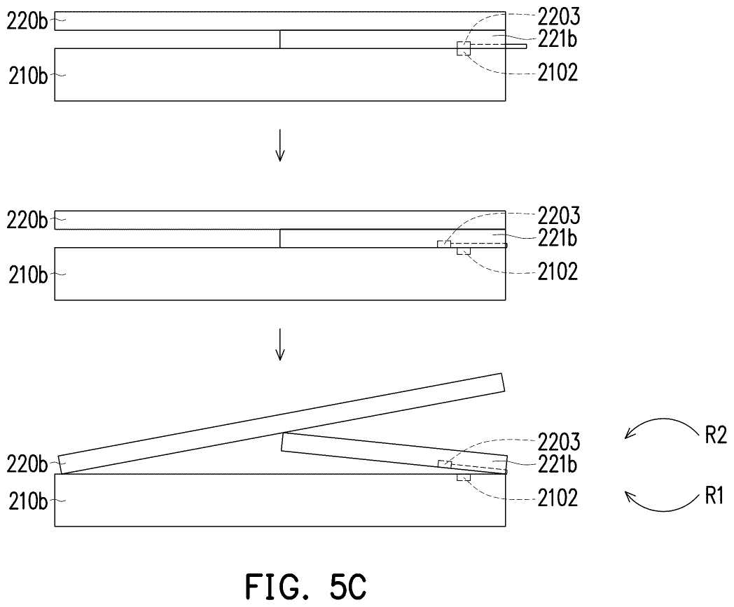

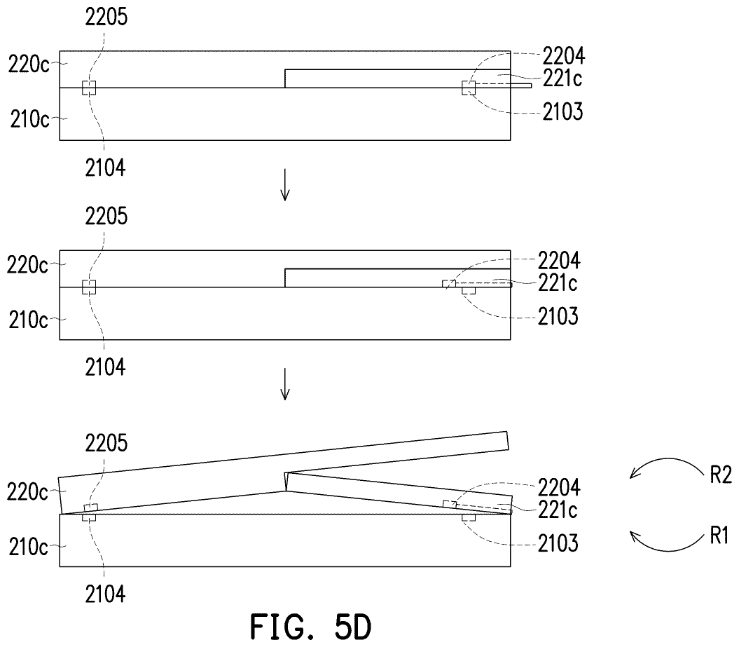

FIG. 5A to FIG. 5D are schematic side views illustrating portable electronic apparatuses according to different embodiments of the disclosure, for illustrating an unfolding mechanism of a second body. As shown in FIG. 5A, a second body 220 may include a display, and is pivotally connected to a first body 210 through a stand 221. The second body 220 is provided with a stop structure 2201 at an end close to a pivot position of the stand 221 and the first body 210, for being in contact with the first body 210 and limiting a rotation sequence of the second body 220. During a process of the second body 220 being folded relative to the first body 210, the second body 220 is required to first be rotated relative to the stand 221 along the second rotation direction R2. After the stop structure 2201 is separated from the first body 210, the second body 220 may be rotated relative to the first body 210 along the first rotation direction R1 through the stand 221, so as to ensure that a display surface of the unfolded second body 220 faces the user.

As shown in FIG. 5B, a second body 220a may include a display, and is pivotally connected to a first body 210a through a stand 221a. The second body 220a is provided with a hook 2202 at an end away from a pivot position of the stand 221a and the first body 210a, and the first body 210a is correspondingly provided with a card slot 2101 for the hook 2202 to be engaged with the card slot 2101 in a folded state. During a process of the second body 220a being unfolded relative to the first body 210a, the second body 220a is required to first be rotated relative to the stand 221a along the second rotation direction R2 to release an engagement relationship between the hook 2202 and the card slot 2101. Then, the second body 220a may be rotated relative to the first body 210a along the first rotation direction R1 through the stand 221a, so that the hook 2202 is moved out of the card slot 2101, and ensures that a display surface of the unfolded second body 220a faces the user.

As shown in FIG. 5C, a second body 220b may include a display, and is pivotally connected to a first body 210b through a stand 221b. The stand 221b is provided with a magnetic button 2203 at an end close to a pivot position with the first body 210b, and the first body 210b is correspondingly provided with a magnetic member 2102 for the magnetic button 2203 to generate magnetic attraction with the magnetic member 2102 in the folded state. During a process of the second body 220b being unfolded relative to the first body 210b, the magnetic button 2203 is required to first be pressed to control the magnetic button 2203 to convert to generating magnetic repulsion to the magnetic member 2102, so as to drive the stand 221b to rotate relative to the first body 210b along the first rotation direction R1, and drive the second body 220b to rotate relative to the stand 221b along the second rotation direction R2, thereby ensuring that a display surface of the unfolded second body 220b faces the user.

As shown in FIG. 5D, a second body 220c may include a display, and is pivotally connected to a first body 210c through a stand 221c. The stand 221c is provided with a sensor button 2204 at an end close to a pivot position with the first body 210c, and the first body 210c is correspondingly provided with a sensing element 2103. In addition, the second body 220c is provided with an electromagnet 2205 at an end away from a pivot position of the stand 221c and the first body 210c, and the first body 210c is correspondingly provided with an electromagnet 2104.

In the folded state, the sensing element 2103 detects the sensor button 2204, and energizes the electromagnet 2205 and the electromagnet 2104 to generate the magnetic attraction for fixing the second body 220c and the first body 210c. During a process of the second body 220b being unfolded relative to the first body 210b, the sensor button 2204 is required to first be pressed, causing the sensing element 2103 to not detect the sensor button 2204 and stop energizing the electromagnet 2205 and the electromagnet 2104. After the magnetic attraction disappears, the second body 220c may be rotated relative to the stand 221c along the second rotation direction R2, and the second body 220c may be rotated relative to the first body 210c along the first rotation direction R1 through the stand 221c, so as to ensure that a display surface of the unfolded second body 220c faces the user.

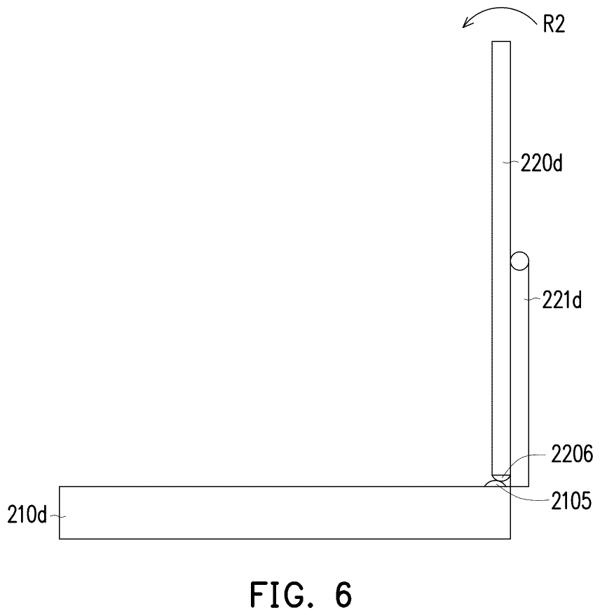

FIG. 6 is a schematic side view illustrating a portable electronic apparatus according to other embodiments of the disclosure, for illustrating a folding mechanism of the second body. As shown in FIG. 6, a second body 220d may include a display, and is pivotally connected to a first body 210d through a stand 221d. The second body 220d is provided with an elastic protrusion 2206 at an end close to a pivot position of the stand 221d and the first body 210d, and the first body 210d is correspondingly provided with an elastic protrusion 2105. During a process of converting from the unfolded state to the folded state, the elastic protrusion 2206 and the elastic protrusion 2105 in contact with each other generate structural interference, preventing the second body 220d from being directly rotated relative to the first body 210d along the second rotation direction R2 with the display surface facing the first body 210d, so as to ensure that a display surface of the second body 220d converted to the folded state may be exposed to the outside.

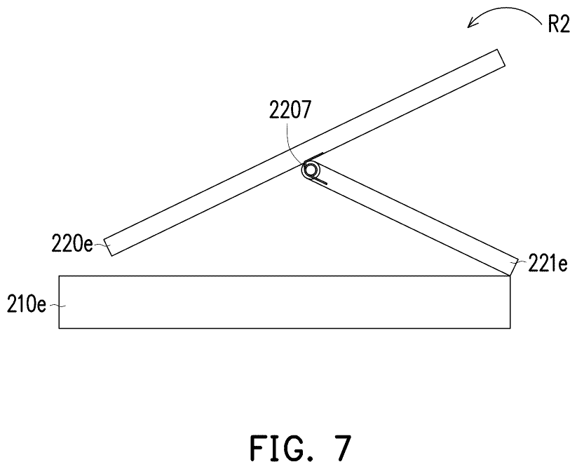

FIG. 7 is a schematic side view illustrating a portable electronic apparatus according to other embodiments of the disclosure, for illustrating the unfolding mechanism of the second body. As shown in FIG. 7, a second body 220e may include a display, and is pivotally connected to a first body 210e through a stand 221e. A torsion spring 2207 is disposed at a pivot position of the second body 220e and the stand 221e. During a process of converting from the folded state to the unfolded state, the originally compressed torsion spring 2207 generates elastic restoration, and pushes the second body 220e to rotate relative to the stand 221e along the second rotation direction R2, so as to ensure that a display surface of the second body 220d converted to the unfolded state may face the user.

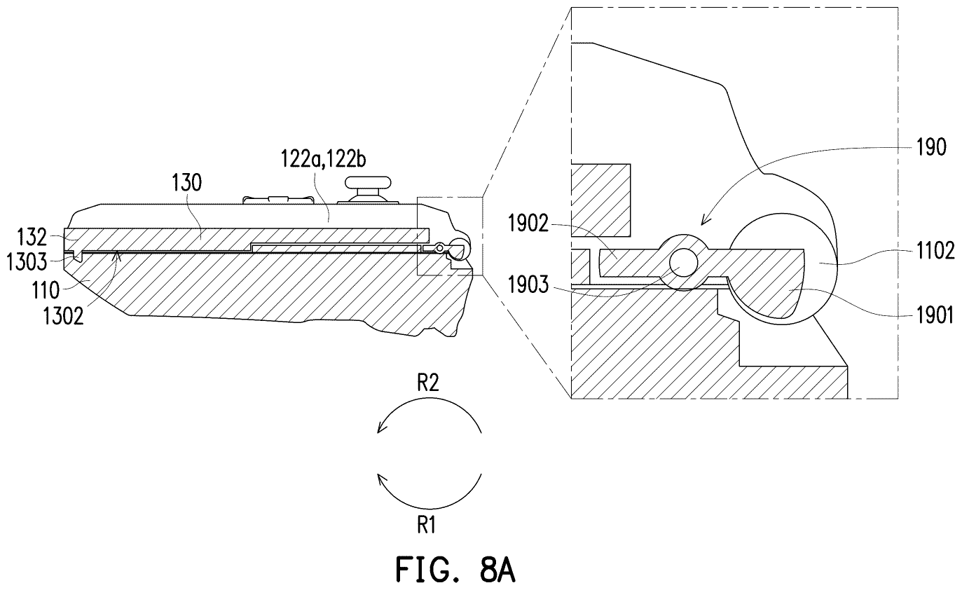

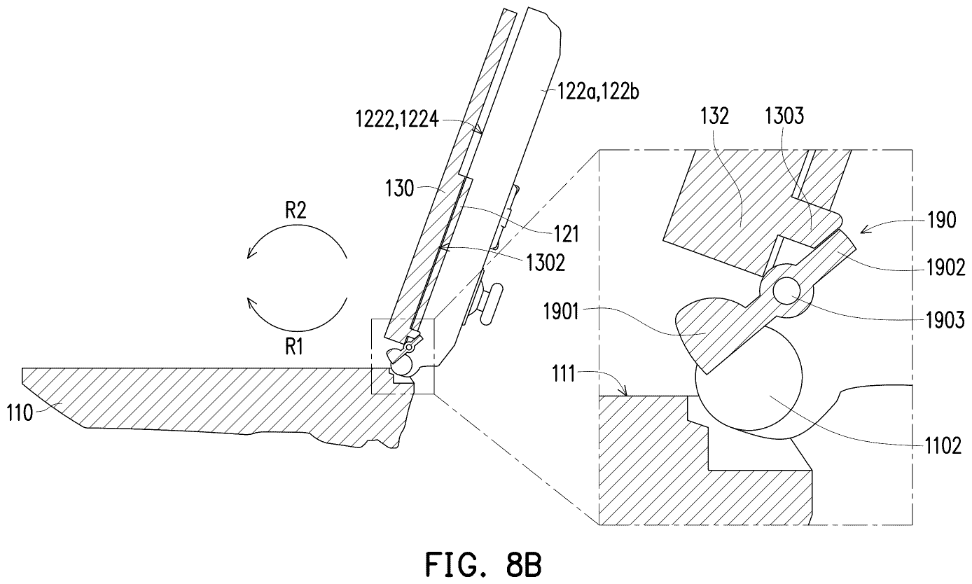

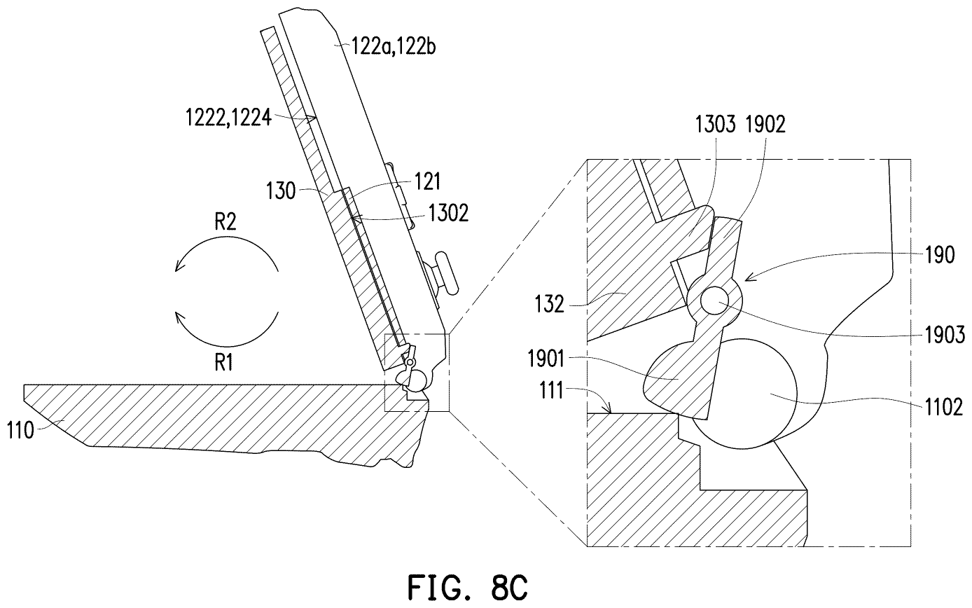

FIG. 8A to FIG. 8C are schematic cross-sectional views of a portable electronic apparatus according to other embodiments of the disclosure, for illustrating a function of the constraint structure disposed between a first body and a second body. To clarify first, as shown in FIG. 8B, in the productivity mode of the portable electronic apparatus in this embodiment, the display 130 protrudes from the second surface 1222 of the control portion 122a and the second surface 1224 of another control portion 122b, rather than being flush with the second surface 1222 of the control portion 122a and the second surface 1224 of another control portion 122b. If the user operates the display 130 to continue rotating along the second rotation direction R2, a lower edge of the display 130 will be in contact with a surface on a periphery of the input module 111 of the first body 110, thereby damaging the display 130. To avoid misoperation behavior by the user, a constraint structure 190 is disposed on a pivot casing 1102 between the two first pivot portions 1101 of the first body 110, referring to FIG. 1D and FIG. 8C together.

Specifically, two ends of the constraint structure 190 are a stop portion 1901 and a contact portion 1902 respectively, and an axle portion 1903 is disposed between the stop portion 1901 and the contact portion 1902, so as to rotatably pivotally connect the constraint structure 190 to the pivot casing 1102 through the axle portion 1903. A convex portion 1303 is disposed on the back side 1302 of the display 130 near the first end portion 132.

As shown in FIG. 8A, in the game mode (correspondingly referring to FIG. 1A), the contact portion 1902 of the constraint structure 190 is in contact with the first body 110, so that the stop portion 1901 is received in the pivot casing 1102. As shown in FIG. 8B, in the productivity mode (correspondingly referring to FIG. 1D), once the back side 1302 is in contact with the stand portion 121, at this time, the convex portion 1303 is also abutted against the contact portion 1902, so as to push the constraint structure 190 to rotate along the first rotation direction R1 according to the axle portion 1903, so that a lower edge of the stop portion 1901 extends out of the pivot casing 1102. As shown in FIG. 8C, when the user operates the display 130 to rotate along the second rotation direction R2, the stop portion 1901 interferes with the surface on the periphery of the input module 111 of the first body 110. By striking of the stop portion 1901 on the surface on the periphery of the input module 111, the user is made aware of the misoperation behavior on the display 130, and stops continuing to force the display 130 to rotate along the second rotation direction R2.

For example, the stop portion 1901 may be made of rubber or silicone to generate moderate deformation when striking the first body 110, avoiding causing damage. In addition, the axle portion 1903 is correspondingly provided with a torsion spring. When the convex portion 1303 pushes the constraint structure 190 to rotate along the first rotation direction R1 according to the axle portion 1903, the torsion spring generates elastic deformation. Once the display 130 is rotated along the first rotation direction R1 such that the convex portion 1303 is separated from the contact portion 1902, restoring elastic force of the torsion spring pushes the constraint structure 190 to rotate along the second rotation direction R2 according to the axle portion 1903 to retract the stop portion 1901 to the pivot casing 1102.

In some examples, the portable electronic apparatus may be provided with a camera module. As shown in FIG. 1A and FIG. 1D, a camera module 2000a may be disposed on the display surface 1301 of the display 130, and located at the second end portion 133.

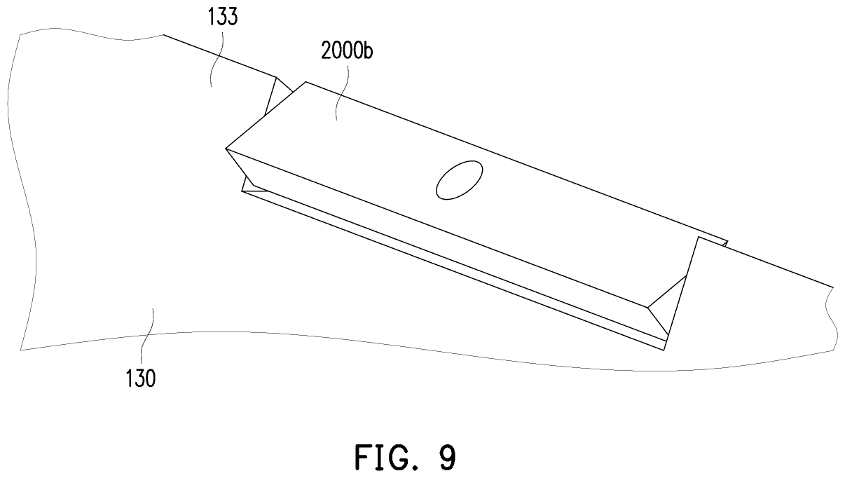

FIG. 9 is a schematic partial enlarged view of a portable electronic apparatus according to other embodiments of the disclosure. As shown in FIG. 9, a camera module 2000b may be pivotally disposed at the second end portion 133 of the display 130. Referring to FIG. 1A and FIG. 1D together, the camera module 2000 b may perform 180-degree rotation switching between the first surface 1221 and the second surface 1222 or the first surface 1223 and the second surface 1224. Compared to the camera module 2000a, the camera module 2000b may provide more options of shooting orientations. For example, in the productivity mode shown in FIG. 1D, in addition to shooting toward a direction of the user, the camera module 2000b may also flip the camera module 2000b to shoot toward another direction facing away from the user.

Based on the above, by flipping the second body relative to the first body, the display may be folded onto the first body along with the second body, or further rotated relative to the stand portion after being unfolded relative to the first body along with the second body, so as to adjust the orientation of the display surface of the display relative to the control portion, thereby performing fast and intuitive switching between the game mode and the productivity mode. On the other hand, the computing module may switch the control signal source of the display according to the mode in which the portable electronic apparatus is in, so as to control the content of the display screen according to the input signal from the control portion in the game mode, and control the content of the display screen according to the input signal from the first body in the productivity mode, eliminating the steps of manual setting.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A portable electronic apparatus, comprising:
a first body;
a first pivot portion;
a second body pivotally connected to the first body through the first pivot portion, and comprising a stand portion and two control portions arranged in parallel, wherein the two control portions are respectively connected to two opposite sides of the stand portion, and the stand portion has a first side facing the first body and a second side opposite to the first side; and
a display disposed between the two control portions, and comprising a second pivot portion, a first end portion, and a second end portion opposite to the first end portion, wherein the second pivot portion is located between the first end portion and the second end portion,
wherein the second pivot portion of the display is pivotally connected to the stand portion of the second body, and the display is adapted to be rotated relative to the stand portion, so that a back side of the display is in contact with the first side or the second side of the stand portion,
when the back side of the display is in contact with the second side of the stand portion, and the display is folded onto the first body along with the second body, a display surface of the display and the two control portions are oriented toward the same side, so that the portable electronic apparatus is in a game mode,
when the display is unfolded relative to the first body along a first rotation direction together with the second body, and the back side of the display is in contact with the first side of the stand portion, the display surface of the display is oriented away from the two control portions, so that the portable electronic apparatus is in a productivity mode.

2. The portable electronic apparatus according to claim 1, wherein the second body has a pivot side and a movable side opposite to each other, and the first pivot portion is located on the pivot side.

3. The portable electronic apparatus according to claim 1, further comprising a driving module, wherein the driving module comprises:
a weight block disposed in the display, and located between the first end portion and the second pivot portion; and
a spring having a fixed end connected to one of the control portions and a driving end directly or indirectly connected to the second pivot portion,
wherein when the display and the second body are operated from the game mode to be synchronously rotated relative to the first body along the first rotation direction to be greater than a preset angle, the first end portion and the second pivot portion are farther from the first body than the second end portion, a first torque is generated on the second pivot portion through the weight block, and the spring generates a second torque opposite to the first torque on the second pivot portion,
the second torque is greater than the first torque to drive the display to rotate relative to the second body along a second rotation direction that is opposite to the first rotation direction, so that the back side of the display is switched from be in contact with the second side to be in contact with the first side.

4. The portable electronic apparatus according to claim 3, wherein a force application position of the driving end of the spring on the second pivot portion is located outside an axle of the second pivot portion.

5. The portable electronic apparatus according to claim 3, wherein the second end portion and the second pivot portion are farther from the first body than the first end portion in the productivity mode.

6. The portable electronic apparatus according to claim 3, wherein the weight block generates a third torque on the second pivot portion when the display is rotated along the second rotation direction to be less than the preset angle, and the third torque is in a same direction as the second torque.

7. The portable electronic apparatus according to claim 3, wherein the spring is a tension spring or a torsion spring, and is directly connected to the second pivot portion.

8. The portable electronic apparatus according to claim 7, wherein the weight block and the fixed end of the spring are located on a same side of the second pivot portion before the display is rotated along the first rotation direction to be greater than the preset angle, and the weight block and the fixed end of the spring are respectively located on two opposite sides of the second pivot portion in the productivity mode.

9. The portable electronic apparatus according to claim 3, wherein the spring is a compression spring, and is indirectly connected to the second pivot portion.

10. The portable electronic apparatus according to claim 9, wherein the weight block and the spring are respectively located on two opposite sides of the second pivot portion before the display is rotated along the first rotation direction to be greater than the preset angle, and the weight block and the spring are located on a same side of the second pivot portion in the productivity mode.

11. The portable electronic apparatus according to claim 9, wherein the second pivot portion is sleeved with a gear, and the driving module further comprises a rack slidably disposed on one of the control portions, the spring is abutted against the rack, and the rack is meshed with the gear.

12. The portable electronic apparatus according to claim 3, wherein the display is in contact with the second side with the second end portion before being rotated along the first rotation direction to be greater than the preset angle, and is in contact with the first side with the first end portion in the productivity mode.

13. The portable electronic apparatus according to claim 3, wherein the preset angle is between 45 degrees and 90 degrees.

14. The portable electronic apparatus according to claim 1, further comprising:
a first magnet disposed at an end of the stand portion away from the second pivot portion; and
a second magnet disposed at the second end portion of the display, and magnetically attracted to the first magnet before the display is rotated along the first rotation direction to be greater than a preset angle.

15. The portable electronic apparatus according to claim 14, further comprising:
a third magnet disposed at the end of the stand portion away from the second pivot portion; and
a fourth magnet disposed at the first end portion of the display, and magnetically attracted to the third magnet in the productivity mode.

16. The portable electronic apparatus according to claim 1, wherein each of the control portions comprises a first module connected to the stand portion and a second module pivotally connected to the first module.

17. The portable electronic apparatus according to claim 16, wherein the first module of each of the control portions is provided with a button or a joystick, the second module is provided with a speaker, and a sound output direction of the speaker is adjusted by rotating the second module.

18. The portable electronic apparatus according to claim 1, wherein each of the control portions has a first surface on which a button or a joystick is located and a second surface opposite to the first surface,
in the game mode, the back side of the display and the second surface of each of the control portions face the first body, and the display surface of the display and the first surface of each of the control portions face the same orientation,
in the productivity mode, the back side of the display and the first surface of each of the control portions face the same orientation, and the display surface of the display and the second surface of each of the control portions face the same orientation.

19. The portable electronic apparatus according to claim 1, wherein the first body is provided with an input module, and the input module comprises one or both of a keyboard module and a touchpad module.

20. A method for using a portable electronic apparatus, comprising the portable electronic apparatus according to claim 1 and a computing module disposed in the first body, wherein the method comprises:
in the game mode, the computing module is adapted to process a first signal from the two control portions to control first screen content displayed on the display surface; and
in the productivity mode, the two control portions are disabled, and the computing module is adapted to process a second signal from the first body to control second screen content displayed on the display surface.

21. The method for using the portable electronic apparatus according to claim 20, wherein each of the control portions is provided with a button or a joystick, and the first signal comprises one or both of a button signal and a joystick signal.

22. The method for using the portable electronic apparatus according to claim 21, wherein the first body is provided with an input module, and the second signal is from the input module.
